(19) United States
(12) Patent Application Publication
(10) Pub. No.: US 2011/0147837 A1
(43) Pub. Date: Jun. 23, 2011

(54) DUAL WORK FUNCTION GATE STRUCTURES

(76) Inventors: Walid M. Hafez, Portland, OR (US); Anisur Rahman, Beaverton, AR (US)

(21) Appl. No.: 12/646,698

(22) Filed: Dec. 23, 2009

(51) Int. Cl. H01L 29/78; H01L 27/092; H01L 21/28

(52) U.S. Cl. 257/338; 257/369; 438/592; 257/E27.062; 257/E29.256; 257/E21.19

(57) ABSTRACT

A semiconductor chip having a transistor is described. The transistor having a gate electrode disposed over a gate dielectric. The gate electrode comprised of first gate material disposed on the gate dielectric and second gate material disposed on the gate dielectric. The first gate material being different than the second gate material. The second gate material also located at a source region or drain region of said gate electrode.

### FIELD OF INVENTION

The field of invention relates generally to semiconductor devices, and, more importantly, to dual work function gate structures.

### BACKGROUND

FIGS. 1 and 2 provide pertinent details concerning complementary semiconductor device technologies such as CMOS. FIG. 1 shows energy band diagrams for the MOS structure of both an NMOS device and a PMOS device at equilibrium. According to the approach of FIG. 1 (which is a common approach), both devices are designed such that, at equilibrium, the Fermi level at the high K dielectric 102_N/NMOS P-well 103_N interface and the Fermi level at the high K dielectric 102_P/PMOS N-well 103_P interface is approximately halfway between the conduction band (Ec) and valence band (Ev). Here, equilibrium essentially corresponds to an “off” device and setting the Fermi level halfway between Ec and Ev keeps the device in its least conductive state (because the conduction band is largely devoid of free electrons and valence band is largely devoid of free holes).

In order to set the Fermi level halfway between Ec and Ev as described above, specific gate metal materials are chosen that induce the proper amount of band bending in the NMOS P-well 103_N and PMOS N-well 103_P. Notably, in order to achieve the desired band bending, the material used for the NMOS gate 101_N typically has a smaller work function 104_N than the material used for the PMOS gate 104_P (that is, the PMOS work function 104_P is typically larger than the NMOS work function 104_N).

FIG. 2 shows the devices of FIG. 1 in the active rather than off state. In the case of the NMOS device, a positive gate-to-source voltage essentially causes additional band bending that places the conduction band beneath the Fermi level at the dielectric/well interface 205_N. When the conduction band Ec is beneath the Fermi level, free electrons are plentiful. Thus, a conductive channel is formed at interface 205_N which corresponds to an “on” device. Likewise, in the case of PMOS device, a negative gate-to-source voltage essentially causes additional band bending that places the valence band above the Fermi level at the dielectric/well interface 205_P. When the valence band Ev is above the Fermi level, free holes are plentiful. Thus, a conductive channel is formed at interface 205_P which corresponds to an “on” device.

### BRIEF DESCRIPTION OF THE DRAWINGS

The present invention is illustrated by way of example and not limitation in the figures of the accompanying drawings, in which like references indicate similar elements and in which:

FIG. 1 show conventional NMOS and PMOS devices at equilibrium;

FIG. 2 show conventional NMOS and PMOS devices in an active mode;

FIGS. 3a and 3b show band diagrams along the channel of a conventional NMOS device;

FIGS. 4a and 4b show band diagrams along the channel of an improved NMOS device;

FIGS. 5a and 5b show band bending diagrams along the channel of an improved PMOS device;

FIGS. 6a through 6f show a conventional dual metal gate manufacturing process;

FIGS. 7a through 7f show a dual metal gate manufacturing process capable of manufacturing the improved devices of FIGS. 4a,b and 5a,b;

FIG. 8a shows an embodiment of an asymmetric NMOS and PMOS devices each having a dual metal gate;

FIG. 8b shows an embodiment of a vertical drain NMOS (VDNMOS) device having a dual metal gate;

FIG. 8c shows an embodiment of a laterally diffused MOS (LDMOS) device having a dual metal gate.

### DETAILED DESCRIPTION OF THE INVENTION

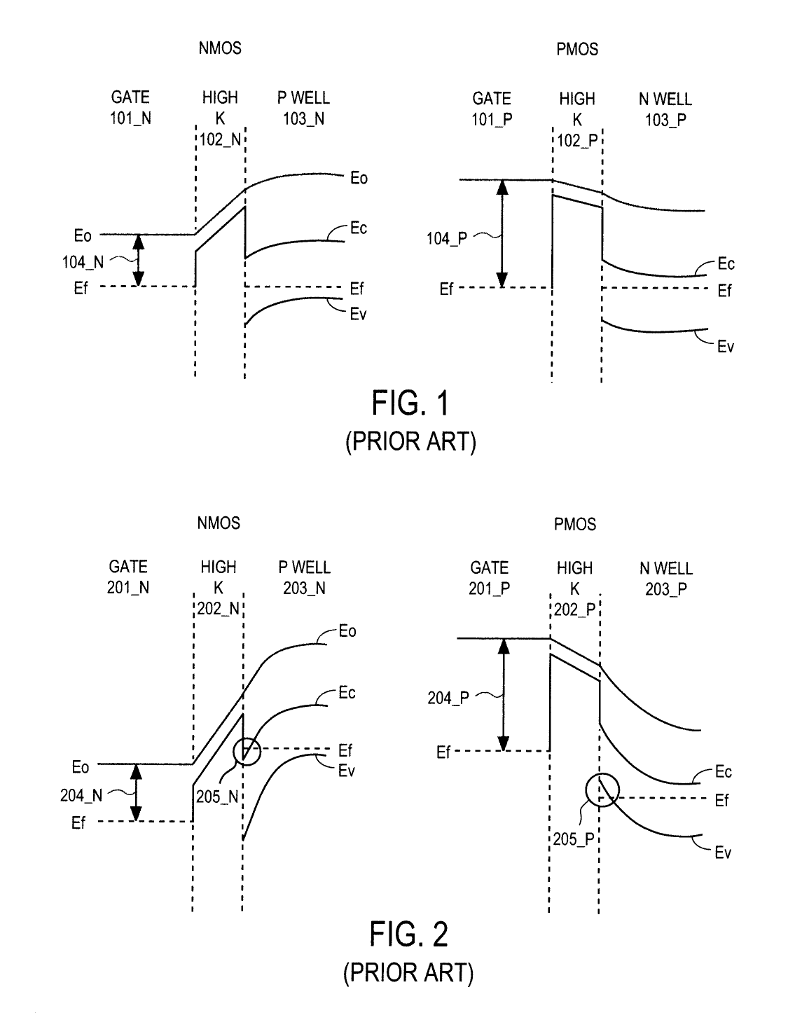

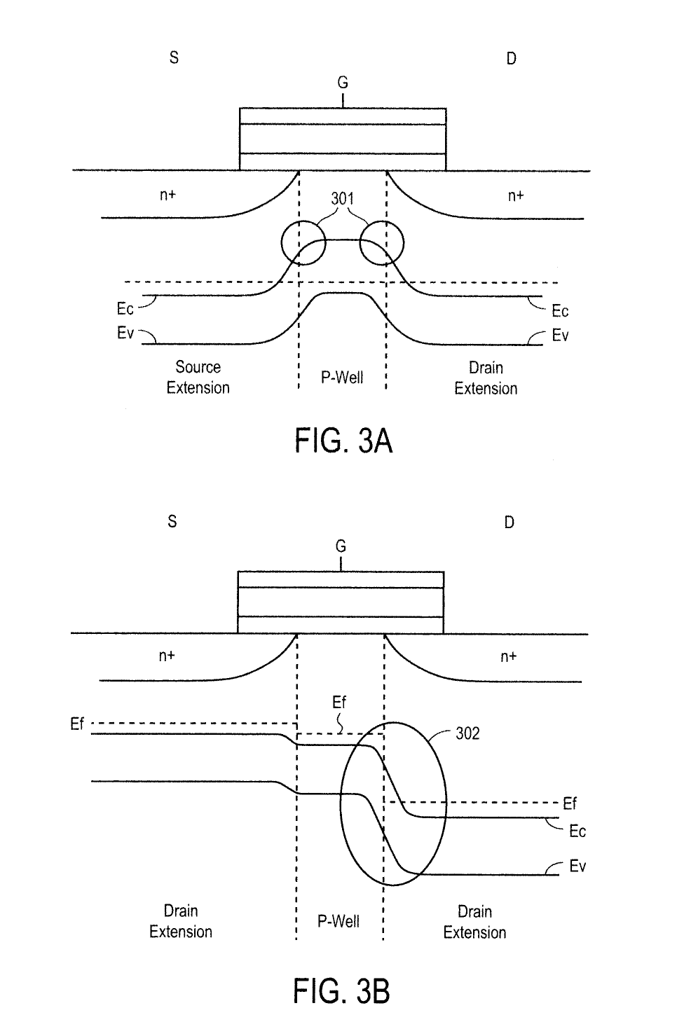

FIGS. 3a and 3b show band diagrams along the channel of the NMOS device described with respect to FIGS. 1 and 2a. FIG. 3a corresponds to the “off” device and FIG. 3b corresponds to the “on” device. Referring to FIG. 3a, the presence of n+ source/drain extensions causes band bending 301 within the P-well. When gate lengths were longer in previous device generations, band bending 301 represented only a small fraction of the energy band profile within the P well beneath the gate. However, with continued gate length reductions, band bending 301 represents a larger and larger percentage of the energy band profile beneath the gate, and, the effects of band bending 301 are becoming increasingly noticeable. For instance, the presence of band bending 301 is believed to contribute to a reduced threshold voltage.

Referring to FIG. 3b, the presence of the n+ drain extension causes sharp band bending 302 near/at the interface of the P well and the n+ drain extension. The sharp bending 302 corresponds to an extremely high electric field that is believed to be the cause of a number of problems associated with “hot carriers” such as substrate currents, avalanche breakdown, lowered energy barriers and threshold shifting.

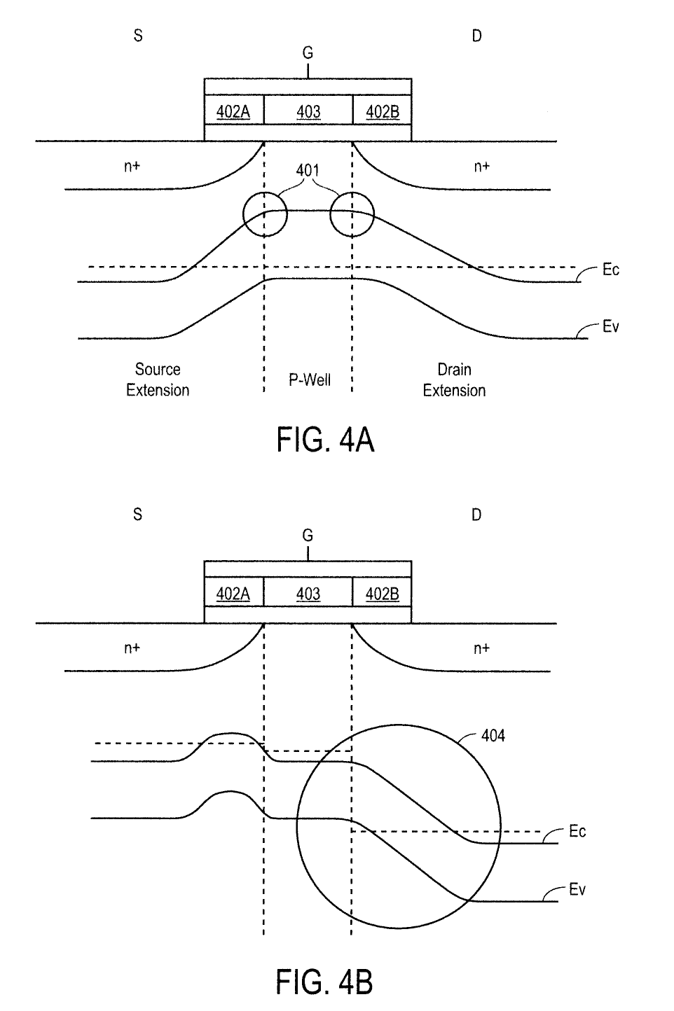

FIGS. 4a and 4b show a design for an NMOS device having improved band bending characteristics beneath the gate electrode as compared to the NMOS device of FIGS. 3a and 3b. FIG. 4a shows the device in the off state and FIG. 4b shows the device in the on state.

Notably, the gate structure of the device can be viewed as having three sections: 1) outer sections 402a and 402b; and, 2) inner section 403. In an embodiment, for an N type device as observed in FIGS. 4a and 4b, the outer sections 402a and 402b are composed of P type device gate metal, and, the inner section 403 is composed of N type device gate metal. Thus, outer sections 402a, 402b have a higher work function than inner section 403.

In this case, the effect of the higher work function material at the outer regions 402a, 402b of the gate have a similar effect as observed for the PMOS device of FIG. 1. That is, the higher work function material induces band bending that pulls the conduction and valence bands “up” relative to the Fermi level as compared to the levels observed in FIG. 3a. As such, the off device of FIG. 4a has less band bending 401 at the P well/extension interface regions than the band bending 301 observed in the device of FIG. 3a. As a consequence, the threshold voltage reduction caused by the presence of the n+ source/drain extensions is practically eliminated or reduced.

Similarly, referring to FIG. 4b, the upward pull on the valence and conduction bands induced by the higher work function material 402b causes less sharp band bending 404 at/near the P well/n+ drain extension in an on device as compared to the on device of FIG. 3b. The less sharp band bending 404 corresponds to a weaker electrical field which should reduce “hot carrier” effects. Band bending is also created at the P well/n+ source extension. As observed in FIG. 4b a small barrier is created however this barrier may be minimized or eliminated with appropriate selection of doping levels and gate metal material.

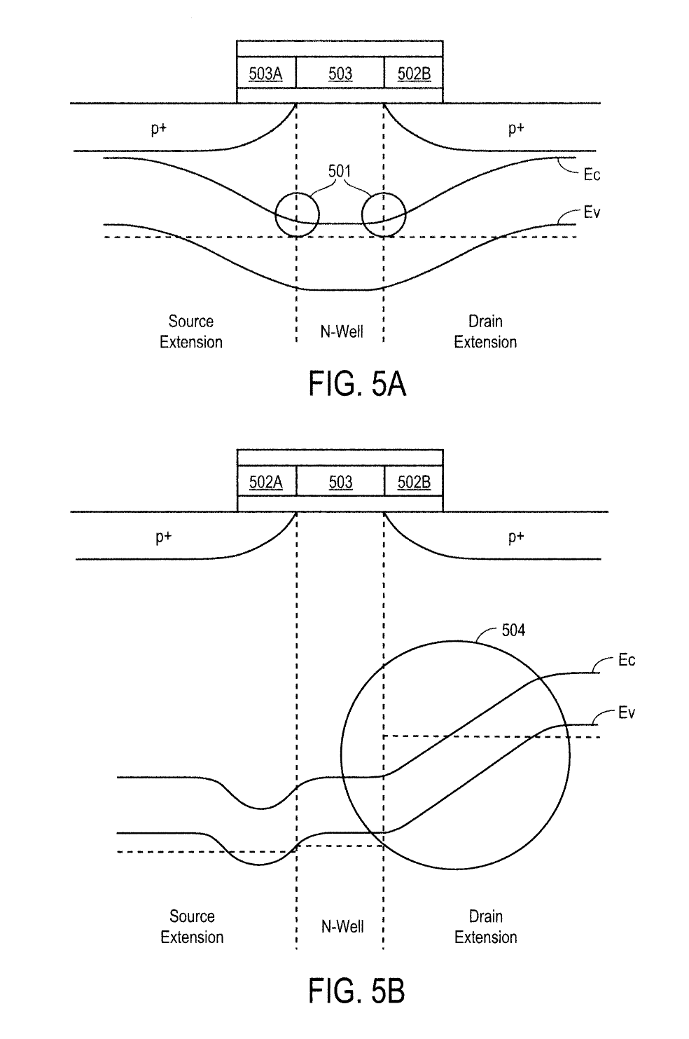

FIGS. 5a and 5b show a design for a PMOS device having improved band bending characteristics beneath the gate electrode as compared to prior art PMOS devices. FIG. 5a shows the device in the off state and FIG. 5b shows the device in the on state.

Notably, the gate structure of the device can be viewed as having three sections: 1) outer sections 502a and 502b; and, 2) inner section 503. In an embodiment, for a P type device as observed in FIGS. 5a and 5b, the outer sections 502a and 502b are composed of N type device gate metal, and, the inner section 503 is composed of P type device gate metal. Thus, outer sections 502a, 502b have a lower work function than inner section 503.

In this case, the effect of the lower work function material at the outer regions 502a, 502b of the gate have a similar effect as observed for the NMOS device of FIG. 1. That is, the lower work function material induces band bending that pulls the conduction and valence bands “down” relative to the Fermi level. As such, the off device of FIG. 5a has less band bending 501 at the N well/extension interface regions than the corresponding band bending at the N well/extension interface regions in prior art (single gate metal) PMOS devices. As a consequence, the threshold voltage reduction caused by the presence of the p+ source/drain extensions is practically eliminated or reduced.

Similarly, referring to FIG. 5b, the downward pull on the valence and conduction bands induced by the lower work function material 502B causes less sharp band bending 504 at/near the N well/p+ drain extension in an on device as compared to a prior art (single gate metal) PMOS device. The less sharp band bending 504 corresponds to a weaker electrical field which should reduce “hot carrier” effects. Band bending is also created at the N well/p+ source extension. As observed in FIG. 5b a small barrier is created however this barrier may be minimized or eliminated with appropriate selection of doping levels and gate metal material.

It is pertinent to point out that, although the terms “NMOS” and “PMOS” are used above in reference to FIGS. 4a,b and 5a,b (which are typically understood to refer to N type Metal Oxide Semiconductor and P type Metal Oxide Semiconductor devices, respectively), for convenience, these terms should be understood to also apply to devices having a gate dielectric that is not technically an oxide. The terms “N type device” and “P type device” may also be utilized. Moreover, although the term “gate metal” is used above in reference to FIGS. 4a,b and 5a,b, the term “gate metal” should be understood to apply to gate materials that are not technically a metal (such as heavily doped polysilicon). The term “gate material”, “gate electrode”, “gate electrode material” and the like may also be utilized. Also, for convenience, the device diagrams do not depict well known device structures such as source/drain electrodes (which are understood to be electrically coupled to their respective source/drain extensions), metal gate fill material residing upon the depicted gate metal of a device, sidewall spacers, etc.

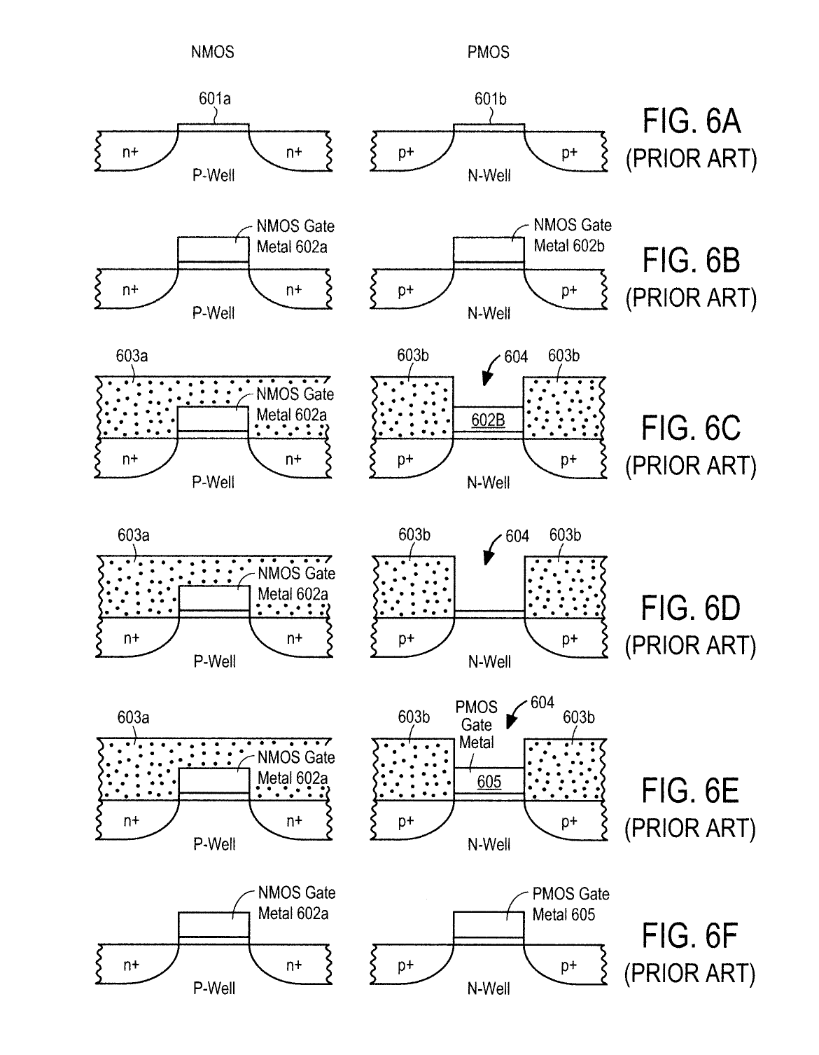

FIGS. 6a through 6f show a prior art process for manufacturing NMOS and PMOS devices having different, respective gate metals. FIG. 6a shows the NMOS and PMOS devices up through deposition of the gate dielectric 601a,b. In FIG. 6b, the gate metal 602a,b for the NMOS device is deposited on the gate dielectric 601a,b of both devices. Then, as observed in FIG. 6c, photoresist 603a,b is coated on the wafer and patterned to form an opening 604 over the gate region of the PMOS device such that the NMOS gate metal 602b residing in the PMOS device is exposed. The NMOS gate material 602a over the NMOS device is covered with photoresist 603a.

As observed in FIG. 6d, the exposed NMOS gate metal 602b in the gate region of the PMOS device is etched away. The NMOS gate metal 602a in the gate region of the NMOS device is protected by the photoresist 603a during the etch. As observed in FIG. 6E, the PMOS gate metal 605 is deposited over the gate dielectric of the PMOS device. The photoresist 603a,b is removed, as observed in FIG. 6f, leaving NMOS gate material 602a in the gate region of the NMOS device and PMOS gate material 605 in the region of the PMOS device. As observed in FIG. 6f, the manufactured devices only have one gate metal on the gate dielectric.

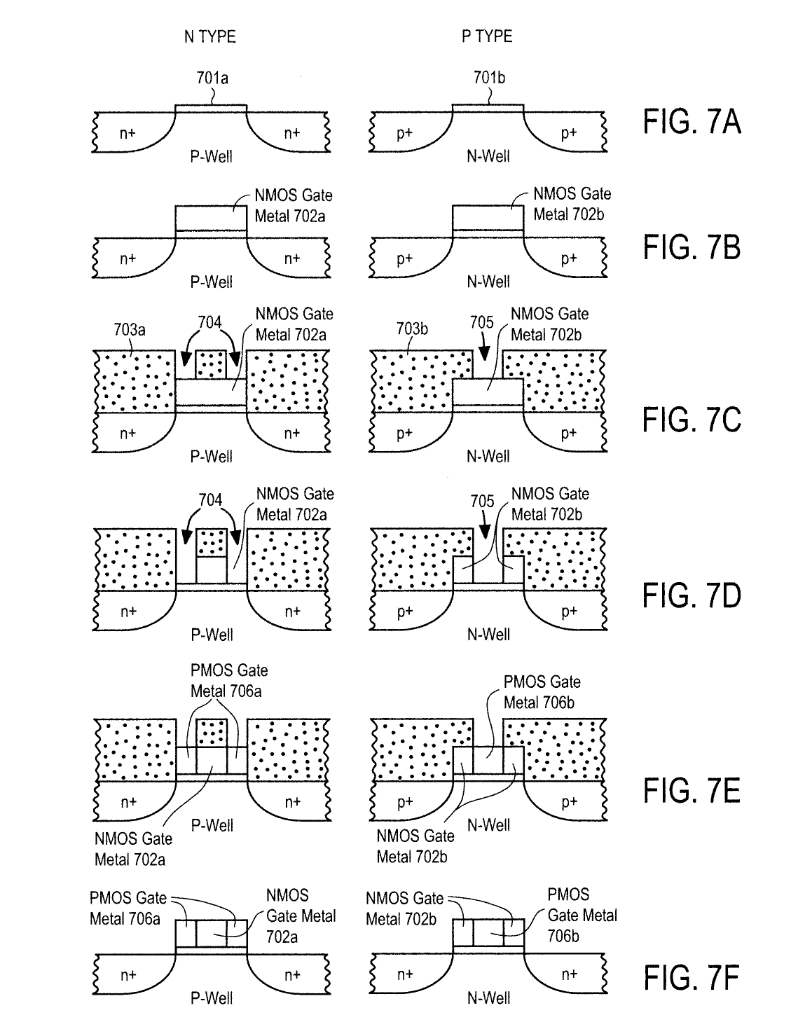

FIGS. 7a through 7f shows a process that, by contrast, can manufacture devices having more than one gate material on the gate dielectric of a single device. FIG. 7a shows the N type and P type devices up through deposition of the gate dielectric 701a, 701b. In FIG. 7b, N type gate material 702a,b is deposited on the gate dielectric of both devices. As observed in FIG. 7c, photoresist 703a,b is coated on the wafer and patterned to form a pair of openings 704 over the gate edges of the N type device, and, a single opening 705 over the gate center of the P type device. Each of the openings expose underlying N type gate material 702a,b. The exposed N type gate material 702b is then etched. The etch may be performed by a dry etch such as an HCl based or SF-6 based etch.

When the exposed N type gate material is removed, P type gate material 706a,b is deposited in its place as observed in FIG. 7e. The photo resist is subsequently removed leaving devices having N and P type gate metal on a gate dielectric.

Notably, in alternate approaches, P type gate material may be deposited before the N type gate material. In this case, the phororesist patterns are “switched” in comparison to FIG. 7b (that is, the P type device will have a pair of openings and the N type device will have a single opening).

The type of materials used for the gate material may vary from embodiment. As discussed above, according to one approach, the gate material used for a P type device (“P type gate material”) is deposited not only on the gate dielectric of a P type device but also on the gate dielectric of an N type device. Likewise, the gate material for an N type device (“N type gate material”) is deposited not only on the gate dielectric of an N type device but also on the gate dielectric of a P type device. Generally, as discussed above, the P type gate material has a higher work function than the N type gate material. Suitable gate materials may include but are not limited to polysilicon, tungsten, ruthenium, palladium, platinum, cobalt, nickel, hafnium, zirconium, titanium, tantalum, aluminum, titanium carbide, zirconium carbide, tantalum carbide, hafnium carbide, aluminum carbide, other metal carbides, metal nitrides, and metal oxides. As is known in the art, the gate materials may be deposited by various processes such as chemical vapor deposition or atomic layer deposition or sputtering.

Although efficiency in terms of the number process steps is achieved when P type gate material is deposited on both P type and N type devices and N type gate material is deposited on both N type devices and P type devices—alternate approaches may use a gate metal that is used on only one of the devices (N type or P type) to engineer the desired band bending. Those of ordinary skill will be able to determine the application and materials when such an approach is warranted.

Also, in an embodiment, the gate lengths of the devices are longer than the minimum gate length that is achievable with the manufacturing process. For instance, in a logic process, typically, the smallest manufactured feature of the logic transistors is the gate length. Thus, devices having gate structures as described herein have longer gate lengths than the logic transistors (because multiple features are formed on a single gate as discussed above rather than a single, smallest manufactured feature as in the case of a logic transistor). For instance, according to one implementation, devices having gate structures as described herein are used to implement higher voltage analog and/or mixed signal circuits. Such devices may be integrated on the same semiconductor device having logic transistors with minimum feature gate lengths. For example, a System on Chip (SOC) having digital components (e.g., processing core, memory, etc.) and analog/mixed signal components (e.g., amplifiers, I/O drivers, etc.)) may use devices having gate structures as described herein for the analog/mixed signal components.

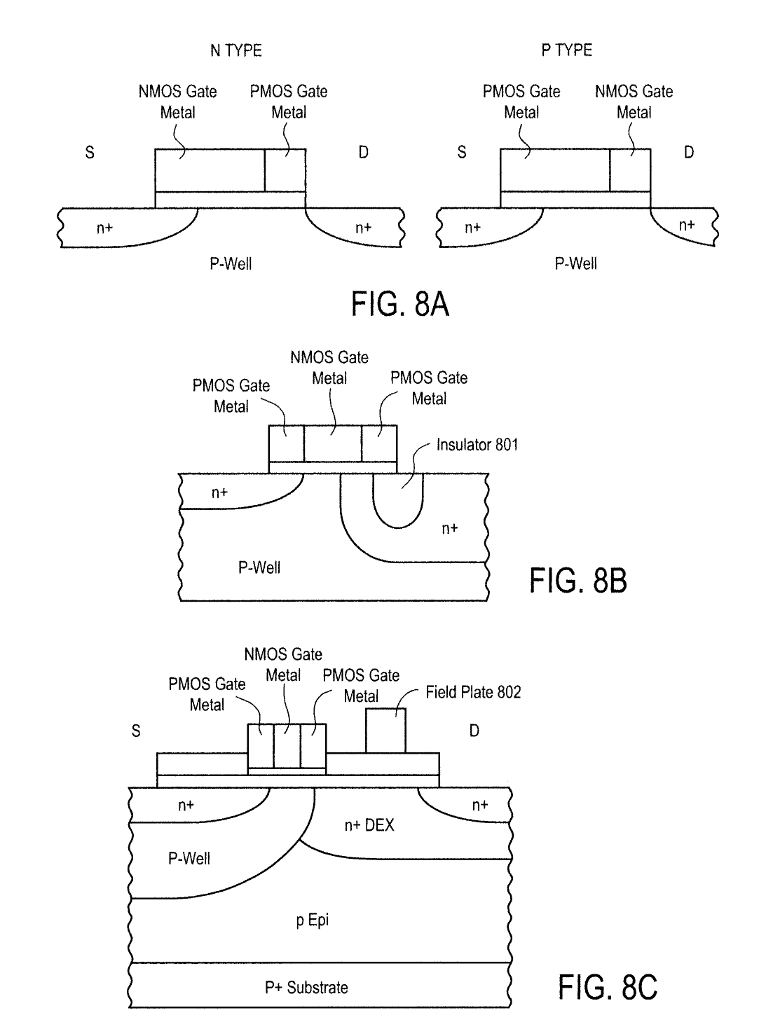

It is also pertinent to point out that although the examples discussed above show strict alignment of the outer gate edge metal with the underlying source/drain extension tips, such an approach is merely exemplary. The positioning of the boundary between the inner gate metal and the outer gate metal of a dual gate metal structure may vary so long as appropriate band bending is achieved. Moreover, as is indicated by FIG. 8a (discussed in more detail immediately below), some device designs may have different outer edge gate material on only one of the edges—e.g., only on the source side or only on the drain side. For example, a device design that is mostly concerned with hot carrier effects may choose to place different outer edge gate material on the drain side of the gate but not the source side of the gate. Likewise, a device design that is less concerned about hot carrier effects and more concerned about a substantially non flat energy band structure beneath the source end of the gate may choose to only add different gate material on the source side of the gate and not the drain side of the gate.

Further still, although the examples discussed above indicate that, in cases where different outer edge gate material exists at both the source and the drain the same gate material is used at both edges, alternative device designs may exist where the pair of outer edge gate materials are different as between themselves. For instance, a first outer edge gate material may be used at the source side of the gate to control the height of the barrier beneath the source side of the gate (observed in FIG. 4b), and, a second outer edge gate material—that is different than the gate material used on the source side—may be used at the drain side to diminish the electric field between the well and the drain junction.

FIGS. 8a through 8c show various kinds of transistors that may be formed with dual metal gate structures as described herein. FIG. 8a shows an N type asymmetrical device and a P type asymmetrical device. Notably, these devices only contain a different outer edge metal near the drain side and not the source side (specifically, the P type gate metal for the N type device, and, the N type gate metal for the P type device). As such, these devices only attempt to impart band bending that reduces the electric field near the well/drain extension.

FIG. 8b shows a Vertical Drain NMOS device (VDNMOS) device having a dual metal gate structure. As is known in the art, a VDNMOS device addresses the problem of a high electric field between the well and drain junction by inserting insulation material 801 beneath the drain edge of the gate. This insertion of a trench 801 creates a high resistance path from the extrinsic drain contact to the gate edge, thereby decreasing the electric field at the region under the gate. In addition, the highly doped drain implants and tips are prevented from encroaching under the gate, which also reduces the peak electric field. These reductions in the field translate to lower carrier energies, and enhanced device reliability.

FIG. 8c shows a laterally diffused MOS (LDMOS) device having a dual metal gate structure. As is known in the art, an LDMOS device addresses the problem of having a high electric field between the well and drain junction by extending the drain extension (DEX) beneath a field plate 802. A field plate 802 acts to spread the field over a larger drain distance, effectively lowering the peak field and enhancing the device lifetime through reduction of hot carrier effects.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

What is claimed is:

1. A semiconductor chip, comprising:
a transistor, said transistor having a gate electrode disposed over a gate dielectric, said gate electrode comprised of first gate material disposed on said gate dielectric and second gate material disposed on said gate dielectric, said first gate material being different than said second gate material, said second gate material also located at a source region or drain region of said gate electrode.

2. The semiconductor chip of claim 1 wherein said transistor is an N type device and said first gate material has a lower work function than said second gate material.

3. The semiconductor chip of claim 1 wherein said first and second gate materials are laterally adjacent to one another on said gate dielectric.

4. The semiconductor chip of claim 3 wherein said semiconductor chip comprises a second transistor, said second transistor being a P type device, said second transistor having a gate electrode comprised of said second gate material disposed on said P type device's gate dielectric.

5. The semiconductor chip of claim 2 wherein said gate electrode comprises third gate material disposed on said gate dielectric, said third gate material disposed at the other of said source region or drain region.

6. The semiconductor chip of claim 5 wherein said third gate material is the same as said second gate material.

7. The semiconductor chip of claim 1 wherein said transistor is a P type device and said first gate material has a lower work function than said second gate material.

8. The semiconductor chip of claim 1 wherein said second gate material is composed of a metal.

9. The semiconductor chip of claim 8 wherein said semiconductor chip comprises a second transistor, said second transistor being an N type device, said second transistor having a gate electrode comprised of said second gate material disposed on said N type device's gate dielectric.

10. A method, comprising:
forming a gate electrode of a transistor by:
depositing a first gate material on a first region of a gate dielectric; and,
depositing a second gate material on a second region of said gate dielectric, said second gate material being at a source or drain side of said gate electrode, said first and second gate materials having different work functions.

11. The method of claim 10 further comprising after said depositing of said first gate material and before said depositing of said second gate material:
coating said first gate material with photoresist;
patterning said photoresist to remove a portion of said photoresist and expose a region of said first gate material; and,
etching said region of said first gate material to expose said second region of gate dielectric, and, wherein, said first gate material and said second gate material are laterally adjacent to one another on said gate dielectric.

12. The method of claim 10 wherein said transistor is an N type transistor and said first gate material has a lower work function than said second gate material.

13. The method of claim 10 wherein said transistor is a P type transistor and said first gate material has a higher work function than said second gate material.

14. The method of claim 10 further comprising, forming a second gate electrode of a second transistor on a same semiconductor die that said gate dielectric is formed on by:
depositing said second material on a first region of second transistor's gate dielectric;
depositing said first material on a second region of said second transistor's gate dielectric, said first material on said second region of said second transistor's gate dielectric being at a source or drain side of said gate second gate electrode.

15. A semiconductor die, comprising:
a N type transistor, said N type transistor having a gate electrode disposed over a gate dielectric, said gate electrode comprised of first gate material disposed on said gate dielectric and second gate material disposed on said gate dielectric, said first gate material having a lower work function than said second gate material, said second gate material also located at a source edge or drain region of said gate electrode; and,
a P type transistor, said P type transistor having a gate electrode disposed over a gate dielectric, said P type transistor's gate electrode comprised of said first gate material disposed on said P type transistor's gate dielectric and said second gate material disposed on said P type transistor's gate dielectric, said P type transistor's first gate material located at a source edge or drain region of said P type transistor's gate electrode.

16. The semiconductor die of claim 15 wherein said N and P type transistors are asymmetric transistors.

17. The semiconductor die of claim 15 wherein said N type transistor is a vertical drain transistor.

18. The semiconductor die of claim 15 wherein said N type transistor is a laterally diffused transistor.

19. The semiconductor die of claim 15 wherein said N and P type transistors are part of an analog circuit or mixed signal circuit, said semiconductor die also having logic circuitry.

20. The semiconductor die of claim 15 wherein said first and second materials are laterally adjacent to each other on the respective gate dielectric of their respective transistors.
